(19) United States
(12) Patent Application Publication
(10) Pub. No.: US 2020/0374430 A1
(43) Pub. Date: Nov. 26, 2020

(54) Magnetic Image Sensor

(71) Applicant: WEIHAI HUALING OPTO-ELECTRONICS CO., LTD, Weihai, Shandong (CN)

(72) Inventors: Li JIANG, Weihai, Shandong (CN); Mingfeng SUN, Weihai, Shandong (CN); Peixiao WANG, Weihai, Shandong (CN); Xiaowei HAN, Weihai, Shandong (CN); Xiumei QI, Weihai, Shandong (CN); Chuanwei QU, Weihai, Shandong (CN)

(21) Appl. No.: 16/618,124

(22) PCT Filed: Aug. 29, 2018
(86) PCT No.: PCT/CN2018/102842

§ 371 Date: Nov. 28, 2019

(30) Foreign Application Priority Data
Dec. 7, 2017 (CN) 201711289129.9

(51) Int. Cl. H04N 5/225; G01R 33/00

(52) U.S. Cl. CPC H04N 5/2254; G01R 33/0017; G01R 33/0094

(57) ABSTRACT

A magnetic image sensor is provided. The magnetic image sensor includes: a permanent magnet, arranged to generate a magnetic field; at least one magnetic induction chip, and each magnetic induction chip converts the magnetic field to at least one electrical signal; a signal processing chip, arranged to receive the at least one electrical signal of each magnetic induction chip and successively output the at least one electrical signal converted by each magnetic induction chip; a signal sampling hold circuit, arranged to perform signal sampling on electrical signals output by the signal processing chip, and perform signal hold on a electrical signal output by the signal processing chip every time before receiving the next electrical signal output by the signal processing chip; and an interface component, arranged to output the electrical signal output by the signal sampling hold circuit.

### TECHNICAL FIELD

The present disclosure relates to the field of image sensors, and in particular to a magnetic image sensor.

### BACKGROUND

Magnetic information has become an important means of modern anti-fake, and the magnetic information is extensively applied in authentic identification of paper money, a financial bill and the like, thus a magnetic image sensor may accurately identify magnetic image information. A magnetic induction resistance chip loaded on the magnetic image sensor may induct the magnetic information and convert the inducted magnetic information into at least one electrical signal under the control of a control chip. The at least one electrical signal is output under the control of a clock signal switch of the control chip. Since a time difference may exist in switching of the clock signal switch, and switch switching noise is existent, at least one output signal of the magnetic image sensor may have smaller downward fluctuation and upward fluctuation. Outputs of different magnetic induction resistance chips in the magnetic sensor have a difference, so output difference fluctuation may also exist between neighboring outputs of different chips. At the same time, since noise in a circuit is blended in the at least one output signal, the output of the magnetic image sensor may also generate the fluctuation. The magnetic sensor may perform larger amplification processing on the at least one output signal, after the larger amplification, the smaller fluctuation on the at least one output signal may be amplified to the very large fluctuation, so that a relatively stable output interval of the at least one output signal is reduced, the at least one output signal may not be effectively sampled, and the at least one output signal may not be stably output. The magnetic image sensor is seriously affected to detect the magnetic image information, so the accuracy of the scanned magnetic image information is greatly reduced.

As to a technical problem in related art that the signal output of the magnetic image sensor is unstable, no effective solution has been provided yet.

### SUMMARY

At least some embodiment of the present disclosure provides a magnetic image sensor, so as at least to partially solve a technical problem in a related art that the signal output of the magnetic image sensor is unstable.

In an embodiment of the present disclosure, a magnetic image sensor is provided, the magnetic image sensor includes: a permanent magnet, arranged to generate a magnetic field; at least one magnetic induction chip, and each magnetic induction chip is located in the magnetic field generated by the permanent magnet and converts the magnetic field to at least one electrical signal; a signal processing chip, connected with the at least one magnetic induction chip, and arranged to receive the at least one electrical signal of each magnetic induction chip and successively output the at least one electrical signal converted by each magnetic induction chip; a signal sampling hold circuit, connected with the signal processing chip, and arranged to perform signal sampling on electrical signals output by the signal processing chip, and perform signal hold on a electrical signal output by the signal processing chip every time before receiving the next electrical signal output by the signal processing chip; and an interface component, connected with the signal sampling hold circuit, and arranged to output the electrical signal output by the signal sampling hold circuit.

In an optional embodiment, the signal processing chip includes a clock input end, arranged to receive a clock control signal, and the signal processing chip is arranged to successively output electrical signals converted by the at least one magnetic induction chip under the trigger of the clock control signal; the signal sampling hold circuit includes a control switch, and the control switch is arranged to be opened or closed under the control of the clock control signal, and control the signal sampling hold circuit to perform signal sampling when the control switch opens, and control the signal sampling hold circuit to perform signal hold when the control switch closes.

In an optional embodiment, the signal sampling hold circuit further includes: a first operation amplifier, and a positive electrode input end of the first operation amplifier is connected with an output end of the signal processing chip, a negative electrode input end of the first operation amplifier is connected with an output end of the first operation amplifier, an output end of the first operation amplifier is further connected with a first end of the control switch, a power source end of the first operation amplifier is connected with a first power source, and a grounding end of the first operation amplifier is grounded; a first capacitor, and a first end of the first capacitor is connected with the power source end of the first operation amplifier and a second end of the first capacitor is connected with the grounding end of the first operation amplifier; a hold capacitor, and a first end of the hold capacitor is connected with a second end of the control switch, and a second end of the hold capacitor is grounded, and the control switch is arranged to control on-off between the first end of the control switch and the second end of the control switch; a second operation amplifier, and a positive electrode input end of the second operation amplifier is connected with a first end of the hold capacitor, a negative electrode input end of the second operation amplifier is connected with an output end of the second operation amplifier, the output end of the second operation amplifier is further connected with an interface component, a power source end of the second operation amplifier is connected with a second power source, and a grounding end of the second operation amplifier is grounded; and a second capacitor, and a first end of the second capacitor is connected with the power source end of the second operation amplifier and a second end of the second capacitor is connected with the grounding end of the second operation amplifier.

In an optional embodiment, the magnetic image sensor further includes: a metal plate, arranged between the permanent magnet and at least one magnetic induction chip, and arranged to uniform the magnetic field generated by the permanent magnet.

In an optional embodiment, the magnetic image sensor further includes: a frame, and the permanent magnet and the metal plate are arranged in the frame.

In an optional embodiment, the magnetic image sensor further includes: a circuit board, arranged to load the at least one magnetic induction chip, the signal processing chip and the signal sampling hold circuit, and the circuit board is arranged at one side of the frame.

In an optional embodiment, the magnetic image sensor further includes: a protecting cover plate, covering an outer side of the circuit board, and arranged to protect the at least one magnetic induction chip, the signal processing chip and the signal sampling hold circuit loaded on the circuit board.

In an optional embodiment, the frame is provided with a through hole, and the interface component is arranged in a position, corresponding to the through hole, on the circuit board.

In an optional embodiment, the magnetic image sensor further includes: a spacer, arranged between the circuit board and the protecting cover plate, and arranged to reserve space between the at least one magnetic induction chip, the signal processing chip and the signal sampling hold circuit loaded on the circuit board and the protecting cover plate.

In an optional embodiment, the protecting cover plate is a stainless steel cover plate.

In the at least some embodiment of the present disclosure, the permanent magnet is arranged to generate the magnetic field, the at least one magnetic induction chip is located in the magnetic field generated by the permanent magnet and each magnetic induction chip converts the magnetic field to the at least one electrical signal, the signal processing chip is connected with the at least one magnetic induction chip and is arranged to receive the at least one electrical signal of each magnetic induction chip and successively output electrical signals converted by the at least one magnetic induction chip, a signal sampling hold circuit is connected with the signal processing chip and is arranged to perform signal sampling on the electrical signal output by the signal processing chip and perform signal hold on a electrical signal output by the signal processing chip every time before receiving the next electrical signal output by the signal processing chip, and an interface component is connected with the signal sampling hold circuit and is arranged to output the electrical signal output by the signal sampling hold circuit, so that the technical problem in the related art that the signal output of the magnetic image sensor is unstable is solved, thereby achieving a technical effect of stabilizing the output signal of the magnetic image sensor.

### BRIEF DESCRIPTION OF THE DRAWINGS

The drawings described herein are used for providing further understanding to the present disclosure, and forming a part of the present application. Schematic embodiments and description thereof of the present disclosure are used for explaining the present disclosure, and not are intended to form inappropriate limitation to the present disclosure. In the drawings:

FIG. 1 is a section schematic diagram of a magnetic image sensor according to an optional embodiment of the present disclosure.

FIG. 2 is a schematic diagram of a signal sampling hold circuit of a magnetic image sensor according to an optional embodiment of the present disclosure.

FIG. 3 is a schematic diagram of a signal sampling waveform of a magnetic image sensor according to the related art.

FIG. 4 is another schematic diagram of a signal sampling waveform of a magnetic image sensor according to the related art.

FIG. 5 is a schematic diagram of a signal sampling waveform of a magnetic image sensor according to an optional embodiment of the present disclosure.

FIG. 6 is a schematic diagram of a signal sampling waveform of a magnetic image sensor according to another optional embodiment of the present disclosure.

### DETAILED DESCRIPTION

In order to make those skilled in the art understand the scheme of the present disclosure better, the technical scheme in the embodiment of the present disclosure is clearly and completely described in combination with the drawings in the embodiment of the present disclosure below. Apparently, the described embodiment is a part of the embodiments of the present disclosure, but not all of the embodiments. Based on the embodiments in the present disclosure, all other embodiments acquired by those of ordinary skill in the art in the precondition without making creative work shall fall within a scope of protection of the present disclosure.

It is to be noted that terms “first”, “second” and the like in the description and the claims and the above drawings in the present disclosure are used for distinguishing similar objects, but not necessarily used for describing a specific sequence or a precedence order. It should be understood that such used data may be interchanged in a suitable situation, so that the embodiments of the present disclosure described herein may be implemented in a sequence besides those illustrated or described herein. In addition, terms “include” and “have” and any transforms thereof are intended to cover non-exclusive inclusion.

The present application provides an embodiment of the magnetic image sensor.

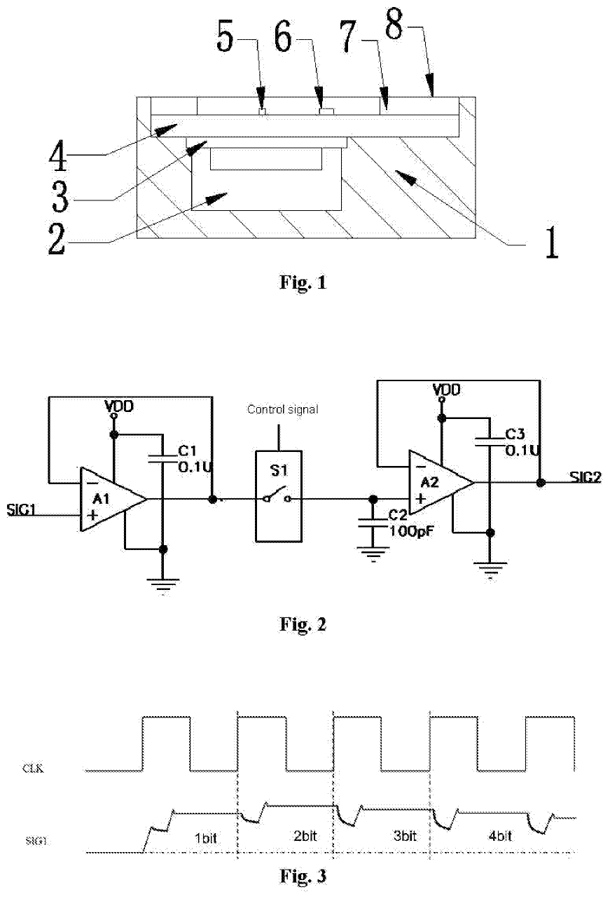

FIG. 1 is a section schematic diagram of a magnetic image sensor according to an optional embodiment of the present disclosure. As shown in FIG. 1, the magnetic image sensor provided by this embodiment includes a permanent magnet 2, at least one magnetic induction chip 5, a signal processing chip 6, and a signal sampling hold circuit and an interface component which are not shown in FIG. 1.

The permanent magnet 2 is arranged to generate a magnetic field. Each magnetic induction chip 5 is located in the magnetic field generated by the permanent magnet 2, and converts the magnetic field to at least one electrical signal. The signal processing chip 6 is connected with the at least one magnetic induction chip 5, and arranged to receive the at least one electrical signal of each magnetic induction chip 5 and successively output the at least one electrical signal converted by each magnetic induction chip 5. The signal sampling hold circuit is connected with the signal processing chip 6, and arranged to perform signal sampling on electrical signals output by the signal processing chip 6, and perform signal hold on a electrical signal output by the signal processing chip 6 every time before receiving the next electrical signal output by the signal processing chip. The interface component is connected with the signal sampling hold circuit, and arranged to output the electrical signal output by the signal sampling hold circuit.

In an optional embodiment, the signal processing chip 6 includes a clock input end, arranged to receive a clock control signal, and the signal processing chip 6 is arranged to successively output electrical signals converted by the at least one magnetic induction chip 5 under the trigger of the clock control signal. The signal sampling hold circuit includes a control switch, and the control switch is arranged to be opened or closed under the control of the clock control signal, and control the signal sampling hold circuit to perform signal sampling when the control switch opens, and control the signal sampling hold circuit to perform signal hold when the control switch closes.

Specifically, as shown in FIG. 2, the signal sampling hold circuit includes a control switch S1. The control switch S1 receives a control signal, and controls open or close according to the control signal, and the control signal received by the control switch S1 is a clock control signal. The signal sampling hold circuit further includes a first operation amplifier A1, a second operation amplifier A2, a first capacitor C1, a hold capacitor C2 and a second capacitor C3. A positive electrode input end of the first operation amplifier A1 is connected with an output end of the signal processing chip 6 (not shown in FIG. 2), an output end of the signal processing chip 6 outputs at least one signal SIG1. A negative electrode input end of the first operation amplifier A1 is connected with an output end of the first operation amplifier A1. An output end of the first operation amplifier A1 is connected with a first end of the control switch S1. A power source end of the first operation amplifier A1 is connected with a first power source VDD. And a grounding end of the first operation amplifier A1 is grounded. The first capacitor C1 is connected between the power source end of the first operation amplifier A1 and the grounding end of the first operation amplifier A1. A first end of the hold capacitor C2 is connected with a second end of the control switch S1, and a second end of the hold capacitor C2 is grounded. And, the control switch S1 is arranged to control on-off between the first end of the control switch S1 and the second end of the control switch S1. A positive electrode input end of the second operation amplifier A2 is connected with a first end of the hold capacitor C2. A negative electrode input end of the second operation amplifier A2 is connected with an output end of the second operation amplifier A2. The output end of the second operation amplifier A2 is connected with the interface component. A power source end of the second operation amplifier A2 is connected with the second power source. In this embodiment, the second power source is also a VDD, and a grounding end of the second operation amplifier A2 is grounded; and the second capacitor C3 is connected between the power source end of the second operation amplifier A2 and the grounding end of the second operation amplifier A2.

FIG. 3 is a schematic diagram of an output signal waveform of a magnetic image sensor according to the related art. As shown in FIG. 3, CLK is a clock control signal, and SIG1 is an output signal of the signal processing chip. Each bit of output of the SIG1 is output one by one under the control of a clock signal. Due to a clock switch time delay difference and the like, the signal has output fluctuation along with bit gaps output before and after a clock signal output period, so that the output has an offset.

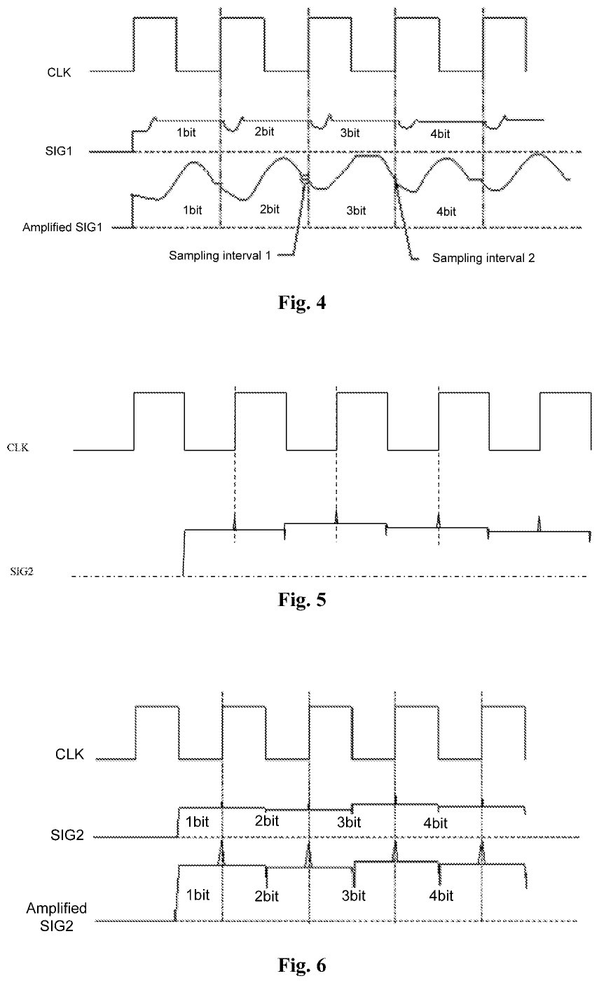

FIG. 4 is an output signal waveform and a waveform of an amplified signal of the signal processing chip in a magnetic image sensor according to the related art. As shown in FIG. 4, the SIG1 is a signal with output fluctuation, after the SIG1 is amplified, a fluctuation signal is amplified so that an effective sampling interval of the signal is reduced (sampling interval 1 as shown in FIG. 4), even the stable sampling interval is not existent (sampling interval 2 as shown in FIG. 4).

After the magnetic image sensor provided by the embodiment of the present disclosure is used, the SIG1 is held through the signal sampling hold circuit, the SIG1 is a magnetic sensor output signal, the SIG1 is firstly input to the input end of the first operation amplifier A1 connected with the signal sampling hold circuit, and input to the input end of the second operation amplifier A2 after passing through the sampling switch S1, and finally output as SIG2 through the second operation amplifier A2. A waveform of the output signal SIG2 is as shown in FIG. 5.

Herein, the control switch S1 may be closed in a low level of the clock control signal CLK. An electrical signal of the SIG1 is capable of rapidly charging the hold capacitor C2 through the first operation amplifier A1. An electrical signal of the hold capacitor C2 is changed along with the SIG1 electrical signal. The signal is sampled and output to the SIG2 and changed along with the SIG1. The control switch S1 is opened in a high level of the CLK signal. At this moment, the output signal of the SIG2 is held in the SIG1 signal while the control switch S1 is opened, always held until the control switch S1 is closed in a next sampling time interval (low level of CLK).

FIG. 6 is a signal after the SIG2 is amplified, as shown in FIG. 6, the fluctuation on the signal is not existent, and the sampling may not be affected after the signal is amplified.

As an optional implementation mode, the magnetic image sensor further includes a metal plate, arranged between the permanent magnet 2 and at least one magnetic induction chip 5, and arranged to uniform the magnetic field generated by the permanent magnet 2.

As an optional implementation mode, the magnetic image sensor further includes a frame, and the permanent magnet 2 and the metal plate are arranged in the frame.

As an optional implementation mode, the magnetic image sensor further includes a circuit board, arranged to load the at least one magnetic induction chip 5, the signal processing chip 6 and the signal sampling hold circuit, and the circuit board is arranged at one side of the frame.

As an optional implementation mode, the magnetic image sensor further includes a protecting cover plate, covering an outer side of the circuit board, and arranged to protect the at least one magnetic induction chip, the signal processing chip and the signal sampling hold circuit loaded on the circuit board.

As an optional implementation mode, the frame is provided with a through hole, and the interface component is arranged in a position, corresponding to the through hole, on the circuit board.

As an optional implementation mode, the magnetic image sensor further includes a spacer, arranged between the circuit board and the protecting cover plate, and arranged to reserve space between the at least one magnetic induction chip, the signal processing chip and the signal sampling hold circuit loaded on the circuit board and the protecting cover plate.

As an optional implementation mode, the protecting cover plate is a stainless steel cover plate.

As an optional implementation mode, as shown in FIG. 1, the magnetic image sensor provided by the embodiment includes a frame 1 for a support function. The frame is internally provided with a permanent magnet 2, and the permanent magnet 2 generates a constant magnetic field. An iron plate (metal plate) 3 is positioned above the permanent magnet 2, the iron plate 3 is capable of enabling a non-uniform magnetic field generated by the permanent magnet 2 to become uniform. A circuit board 4 is positioned above the iron plate 3. The circuit board 4 mainly realizes basic circuit connection and signal output. A magnetic induction resistance chip (magnetic induction chip) 5 and a signal processing chip 6 are loaded on the circuit board 4. The magnetic induction chip 5 may change a resistance value while magnetic information is detected because of a change of a magnetic field caused by which the magnetic information passes through above the magnetic induction chip 5. A change of the resistance value of the magnetic induction chip 5 may become at least one voltage signal. The at least one voltage signal is successively output by the signal processing chip 6. A spacer 7 is positioned on the circuit board 4. A stainless steel protecting cover plate 8 is positioned above the spacer 7. The stainless steel protecting cover plate 8 is capable of protecting chips loaded on the circuit board 4. The spacer 7 is capable of enabling the circuit board 4 to be tightly combined with the stainless steel protecting cover plate 8 for a protection function, reserving space above the magnetic induction chip 5 and the signal processing chip 6, thereby achieving an effect of protecting the chips. At the same time, the spacer 7 achieves a support effect to the protecting cover plate 8 above the spacer.

The above are optimal implementation modes of the present application, it should be indicated that those of ordinary skill in the art may also make a plurality of improvements and decorations in the precondition without departing from a principle of the present application, and these improvements and decorations shall also be regarded as a scope of protection of the present application.

What is claimed is:

1. A magnetic image sensor, comprising:
a permanent magnet, arranged to generate a magnetic field;
at least one magnetic induction chip, wherein each magnetic induction chip is located in the magnetic field generated by the permanent magnet and converts the magnetic field to at least one electrical signal;
a signal processing chip, connected with the at least one magnetic induction chip, and arranged to receive the at least one electrical signal of each magnetic induction chip and successively output the at least one electrical signal converted by each magnetic induction chip;
a signal sampling hold circuit, connected with the signal processing chip, and arranged to perform signal sampling on electrical signals output by the signal processing chip, and perform signal hold on a electrical signal output by the signal processing chip every time before receiving the next electrical signal output by the signal processing chip; and
an interface component, connected with the signal sampling hold circuit, and arranged to output the electrical signal output by the signal sampling hold circuit.

2. The magnetic image sensor as claimed in claim 1, wherein
the signal processing chip comprises a clock input end, arranged to receive a clock control signal, wherein the signal processing chip is arranged to successively output electrical signals converted by the at least one magnetic induction chip under the trigger of the clock control signal; and
the signal sampling hold circuit comprises a control switch, and the control switch is arranged to be opened or closed under the control of the clock control signal, and control the signal sampling hold circuit to perform signal sampling when the control switch opens, and control the signal sampling hold circuit to perform signal hold when the control switch closes.

3. The magnetic image sensor as claimed in claim 2, wherein the signal sampling hold circuit further comprises:
a first operation amplifier, wherein a positive electrode input end of the first operation amplifier is connected with an output end of the signal processing chip, a negative electrode input end of the first operation amplifier is connected with an output end of the first operation amplifier, an output end of the first operation amplifier is further connected with a first end of the control switch, a power source end of the first operation amplifier is connected with a first power source, and a grounding end of the first operation amplifier is grounded;
a first capacitor, wherein a first end of the first capacitor is connected with the power source end of the first operation amplifier and a second end of the first capacitor is connected with the grounding end of the first operation amplifier;
a hold capacitor, wherein a first end of the hold capacitor is connected with a second end of the control switch, and a second end of the hold capacitor is grounded, and the control switch is arranged to control on-off between the first end of the control switch and the second end of the control switch;
a second operation amplifier, wherein a positive electrode input end of the second operation amplifier is connected with a first end of the hold capacitor, a negative electrode input end of the second operation amplifier is connected with an output end of the second operation amplifier, the output end of the second operation amplifier is further connected with an interface component, a power source end of the second operation amplifier is connected with a second power source, and a grounding end of the second operation amplifier is grounded; and
a second capacitor, wherein a first end of the second capacitor is connected with the power source end of the second operation amplifier and a second end of the second capacitor is connected with the grounding end of the second operation amplifier.

4. The magnetic image sensor as claimed in claim 1, wherein the magnetic image sensor further comprises:
a metal plate, arranged between the permanent magnet and at least one magnetic induction chip, and arranged to uniform the magnetic field generated by the permanent magnet.

5. The magnetic image sensor as claimed in claim 4, wherein the magnetic image sensor further comprises:
a frame, wherein the permanent magnet and the metal plate are arranged in the frame.

6. The magnetic image sensor as claimed in claim 5, wherein the magnetic image sensor further comprises:
a circuit board, arranged to load the at least one magnetic induction chip, the signal processing chip and the signal sampling hold circuit, and the circuit board is arranged at one side of the frame.

7. The magnetic image sensor as claimed in claim 6, wherein the magnetic image sensor further comprises:
a protecting cover plate, covering an outer side of the circuit board, and arranged to protect the at least one magnetic induction chip, the signal processing chip and the signal sampling hold circuit loaded on the circuit board.

8. The magnetic image sensor as claimed in claim 7, wherein the frame is provided with a through hole, and the interface component is arranged in a position, corresponding to the through hole, on the circuit board.

9. The magnetic image sensor as claimed in claim 7, wherein the magnetic image sensor further comprises:
a spacer, arranged between the circuit board and the protecting cover plate, and arranged to reserve space between the at least one magnetic induction chip, the signal processing chip and the signal sampling hold circuit loaded on the circuit board and the protecting cover plate.

10. The magnetic image sensor as claimed in claim 7, wherein the protecting cover plate is a stainless steel cover plate.
